(19) United States
(12) Patent Application Publication
(10) Pub. No.: US 2026/0360445 A1
(43) Pub. Date: Nov. 12, 2026

(54) SENSE AMPLIFIER FOR A NON-VOLATILE MEMORY DEVICE STORING CODED INFORMATION AND CORRESPONDING NON-VOLATILE MEMORY DEVICE

(71) Applicant: STMicroelectronics International N.V., Geneva (CH)

(72) Inventors: Marcella CARISSIMI, TREVIOLO (IT); Cesare TORTI, PAVIA (IT); Fabio Enrico Carlo DISEGNI, Spino d'adda (IT); Riccardo DEL GAUDIO, Milano (IT)

(73) Assignee: STMicroelectronics International N.V., Geneva (CH)

(21) Appl. No.: 19/657,921

(22) Filed: Apr. 24, 2026

(30) Foreign Application Priority Data
May 6, 2025 (IT) 102025000010107

(51) Int. Cl. G11C 16/28; G11C 5/14; G11C 16/24

(52) U.S. Cl. CPC G11C 16/28; G11C 5/147; G11C 16/24

(57) ABSTRACT

A sense amplifier, for a non-volatile memory device having a plurality of memory cells organized in wordlines and bitlines, wherein groups of memory cells store respective symbols formed by stored logic states; the sense amplifier has: a number of reading branches, each one coupled, during a reading process, to a respective bitline of an addressed memory cells of a respective group and configured to provide output currents based on a respective cell current flowing through the addressed memory cell; a number of first comparators, coupled to a respective pair of the reading branches to compare a respective pair of the output currents to provide first comparison output signals; a second comparator, coupled to the reading branches to compare a sum of the respective output currents with a reference current to provide a second comparison output signal; and a decoding logic, to determine, based on the first and second comparison output signals, a read symbol. The sense amplifier further has a reference branch, to provide the reference current and coupled to a number of dummy bitlines associated with memory cells not selected for the reading process, the dummy bitlines corresponding in number to the bitlines of the addressed memory cells of the respective group.

### BACKGROUND

### Technical Field

The present disclosure relates to an improved sense amplifier for embedded non-volatile memory devices (e-NVM), where information is stored in a coded manner. In particular, the present disclosure will refer to non-volatile memories where stored information are associated with a current flowing through corresponding memory cells, more in particular to Phase Change Memories (PCM).

### Description of the Related Art

In PCM memories the characteristics of materials having the property of switching between phases with a different electrical behaviour are exploited for storing information in memory cells; in particular, a chalcogenide alloy formed by germanium (Ge), antimonium (Sb), and tellurium (Te), known as GST (having the chemical composition Ge₂Sb₂Te₅), is currently used in such memory cells. This alloy can switch reversibly and controllably between a disorderly/amorphous phase and an orderly crystalline or polycrystalline phase: the crystalline phase has a low resistance and corresponds to a ‘Set’ state and the amorphous phase has a high resistance and corresponds to a ‘Reset’ state.

Phase changes are obtained by locally increasing the temperature of the cells of chalcogenic material, through the Joule effect, via the passage of a programming electric current, which is enabled by access (or selection) devices, for example bipolar (BJT) transistors. During reading, the state of the chalcogenic material is detected by applying a voltage that is sufficiently low so as not to cause a sensitive heating thereof and then reading the value of the current flowing in the memory cell through a sense amplifier circuit. Since the current is proportional to the conductivity of the chalcogenic material, it is possible to determine the state of the same material and consequently the information stored in the memory cell.

FIG. 1 schematically shows a non-volatile storage device 1, comprising a memory array 2 formed by a plurality of memory cells 3, arranged in rows, or wordlines WL, and columns, or bitlines. Each memory cell 3 is formed by a storage element 3a and by an access element 3b, which are series-connected between a respective local bitline LBL and a terminal at a reference potential (for example ground, GND). A wordline WL is defined by the set of all control terminals of access elements 3b aligned along a same row. In a manner not shown, main bitlines MBL are provided for each set of a number of local bitlines LBL, allowing to access the respective set of local bitlines (and corresponding memory cells) for reading and writing operations.

The storage element 3a includes a phase-change material element (for example, a chalcogenide, such as GST) and is consequently able to store data in the form of levels of resistance associated with the various phases assumed by the same material. The access element 3b is, in the example, a pnp BJT transistor having its base terminal connected to a respective wordline WL, its emitter terminal connected to a first terminal of the storage element 3a, and its collector terminal connected to the reference potential; a second terminal of the storage element 3a is connected to a corresponding local bitline LBL. The access element 3b is controlled and biased so as to enable, when selected, the passage of a writing current or of a reading current (denoted, in general, as ‘cell current’), through the storage element 3a.

A column decoder 4 and a row decoder 5 enable selection of the memory cells 3, on the basis of address signals received, at an input (designated as a whole by AS) and suitable decoding schemes. The address signals AS can be generated by a control logic CL, which moreover controls the column decoder 4 and the row decoder 5 so as to enable reading and writing (during so called ‘SET’ and ‘RESET’ operations) of the memory cells 3 addressed by the address signals AS. In particular, the column decoder 4 and the row decoder 5 enable selection of the wordlines WL and of the main and local bitlines MBL, LBL, and therefore enable biasing at appropriate voltage values of the wordlines WL and local bitlines LBL selected.

The column decoder 4 is further configured to internally implement two distinct paths towards the local bitlines LBL of the memory array 2 each time selected: a reading path, designed to selectively create a conductive path between each selected local bitline LBL and a read block 7, which includes a plurality of sense amplifiers; and a writing path, designed to selectively create a conductive path between each selected local bitline LBL and a write block 8 configured to supply the currents for the writing operations. The column decoder 4 comprises, for each reading and programming path, appropriate selection elements (in particular, controlled transistors), connected so as to implement an address-decoding system, which is typically hierarchical, for selection of the memory cells 3.

Traditional non-volatile memories have a differential architecture, wherein data (logic bits) are stored in two memory cells, a direct cell and a complementary cell, having opposite states (for example, a direct cell having a high, ‘1’, logic value and a corresponding complementary cell having a low, ‘0’, logic value, i.e., a negated value with respect to the direct cell). This differential encoding, i.e., storing not only the actual direct value (one or zero), but also its negated or complementary value (zero or one) in a pair of memory cells, allows to avoid problems due to drifting of the stored values during the life of the memory cells and thus improve reliability and robustness of the memory operation.

In the differential architecture, reading operations consist in comparing, by a respective sense amplifier, the currents from the direct and complementary cells (accessed via respective main bitline MBL and local bit line LBL), the output of the sense amplifier being indicative of the stored information (logic bit).

A drawback of the differential architecture is the doubled number of memory cells used to store a same amount of information or, equivalently, the halved number of information bits that can be stored using a same number of memory cells, so that the efficiency of a differential memory array (e.g., of the PCM type) usually does not exceed 50%.

In order to address this issue (and due to the fact that area density is a key parameter in several applications), an alternative encoding methodology aimed at reducing the memory array's area occupation and improving write throughput has been proposed, e.g., in EP 4 210 054 A1 in the name of the present Applicant.

This memory architecture, in a possible embodiment that may be referred to as 3 Cells/2 Bits (3C/2B), allows to store two bits in three cells, instead of four cells as in the traditional 2 Cells/1 Bit (2C/1B) solution, allowing to spare 25% of storage array cell area while maintaining a similar reliability as compared to the differential architecture.

In the 3C/2B architecture, data stored in three memory cells, identified as Cell_A, Cell_B and Cell_C in the Table below, determine symbols (or codewords) of two bits according to the mapping relationship shown in the same Table.

| Symbol | Cell_A | Cell_B | Cell_C |
|---|---|---|---|
| 11 | Set(1) | Set(1) | Reset(0) |
| 10 | Set(1) | Reset(0) | Set(1) |
| 01 | Reset(0) | Set(1) | Set(1) |
| 00 | Reset(0) | Reset(0) | Reset(0) |

Cell_A contains the value of the most significant bit, Cell_B contains the value of the least significant bit, and Cell_C is programmed with the XOR operation result of the two bits. The definition of cell states is chosen such that in each symbol ‘11’, ‘10’, ‘01’ or ‘00’ two cells are in the Set state but at different position (these cells belonging to a first subset, ‘subset 1’) or no Set state is present (this cell belonging to a second subset, ‘subset 0’).

In this architecture, three main bit lines MBLs are thus connected to each sense amplifier and each sense amplifier is able to define and output two bits of the corresponding stored symbol. In particular, the reading process in each sense amplifier is based on four simultaneous evaluations: one reading for comparing the sum S of the currents of the cells with a reference current, I_{ref}, so as to decide the subset to which the symbol belongs; and three differential readings, for comparing cells Cell_A, Cell_B, and Cell_C in pairs, so as to decide the symbol in the subset (in particular, within ‘subset 1’). The output comparisons may be processed with a combinational logic to extract the equivalent symbol information (bits).

This sense amplifier architecture provides for a more efficient and compact memory array and also implements a protection from drifts. The same architecture, however, poses some challenges in the implementation of the related sense amplifiers (SA), in particular concerning matching of capacitive loads and the lack of a “verify” function (i.e., the operation that occurs after the writing phase, which allows checking the recently written cell by comparing it with a reference current). Moreover, a greater number of comparators per bit is used as compared to traditional differential architectures (for 2 bit, the sense amplifier SA utilizes four comparators, while the standard solution utilizes two), generally resulting in a larger area occupation and in a higher current consumption.

According to the above, a need is felt to provide an improved solution for a sense amplifier for a non-volatile memory device storing coded information, as the one previously discussed.

### BRIEF SUMMARY

The present disclosure provides a sense amplifier architecture that will satisfy, at least in part, the above need.

According to the present solution, a sense amplifier and a corresponding non-volatile memory device are provided.

A sense amplifier is for a non-volatile memory device having a plurality of memory cells organized in wordlines and bitlines, where groups of memory cells store respective symbols formed by stored logic states. The sense amplifier has: a number of reading branches, each one coupled, during a reading process, to a respective bitline of an addressed memory cells of a respective group and configured to provide output currents based on a respective cell current flowing through the addressed memory cell; a number of first comparators, coupled to a respective pair of the reading branches to compare a respective pair of the output currents to provide first comparison output signals; a second comparator, coupled to the reading branches to compare a sum of the respective output currents with a reference current to provide a second comparison output signal; and a decoding logic, to determine, based on the first and second comparison output signals, a read symbol. The sense amplifier further has a reference branch, to provide the reference current and coupled to a number of dummy bitlines associated with memory cells not selected for the reading process, the dummy bitlines corresponding in number to the bitlines of the addressed memory cells of the respective group.

### BRIEF DESCRIPTION OF THE SEVERAL VIEWS OF THE DRAWINGS

For a better understanding of the present solution, various embodiments thereof will now be described, purely by way of non-limiting examples, with reference to the attached drawings, wherein:

FIG. 1 shows a schematic and general block diagram of a non-volatile memory device, in particular of the PCM type;

FIG. 2 shows a schematic block diagram related to a sense amplifier according to an embodiment of the present solution;

FIGS. 3-5 show circuit diagrams of respective portions of the sense amplifier;

FIG. 6 shows a block diagram of a digital decoding logic of the sense amplifier;

FIG. 7 shows a diagram of signals related to operations performed by the sense amplifier;

FIG. 8 shows a block diagram of an error detection logic of the sense amplifier;

FIG. 9 shows a circuit diagram of a portion of the sense amplifier, according to a further embodiment of the sense amplifier; and

FIG. 10 shows a schematic block diagram of an electronic apparatus that incorporates a memory device that includes the present sense amplifier architecture.

### DETAILED DESCRIPTION

As shown in FIG. 2, a sense amplifier according to an embodiment of the present solution, denoted with 10, is coupled to memory cells, again denoted with 3, of the memory array 2; the memory array 2 is divided into a number of different sectors (two of these sectors are shown in FIG. 2, as an example, S_0 and S_1), each including a plurality of respective memory cells 3. In the example, a first sector, S_0, is addressed for a reading operation (the respective word line is active, ON), while a second sector, S_1, is not addressed for the same reading operation (the respective word line is inactive, OFF).

The sense amplifier 10 is coupled to main bit lines MBL via first-level decoding transistor TYn of the column decoder 4, receiving control signals Yn; second-level decoding transistor TYo of the column decoder 4, receiving control signals Y0, selectively connect the local bit line LBL of the memory cells 3 to be addressed to the main bit line MBL (and thus to the sense amplifier 10).

As discussed above, a plurality of sense amplifiers 10 are associated to the memory array 2 (one is shown in FIG. 2), included in the above referenced read block 7 coupled to the column decoder 4, in order to perform reading operations.

According to an embodiment of the present solution, the sense amplifier 10 is coupled, during a reading operation: to three memory cells 3 of the first sector, S_0 (denoted again as Cell_A, Cell_B and Cell_C) storing the data to be read in a coded manner, for example according to the 3C/2B encoding scheme, via respective MBLs and LBLs; and moreover to three memory cells 3 of the not-addressed second sector, S_1 (denoted as Cell′, which are not selected and are not biased for reading), via respective “dummy” bit lines (i.e., not associated with cells to be read), denoted with D_BL.

As will be discussed in the following, the three dummy bitlines D_BL constitute respective dummy load paths, which allows to achieve a capacitive matching during reading of the three addressed bitlines, matching the capacitive load of the three reading branches associated with the addressed memory cells Cell_A, Cell_B and Cell_C.

The sense amplifier 10 is configured to implement a decoding of the information stored in the coded manner in the groups of memory cells 3 by comparing, between each other (e.g., with pairwise comparisons), the currents of the memory cells in the groups of cells.

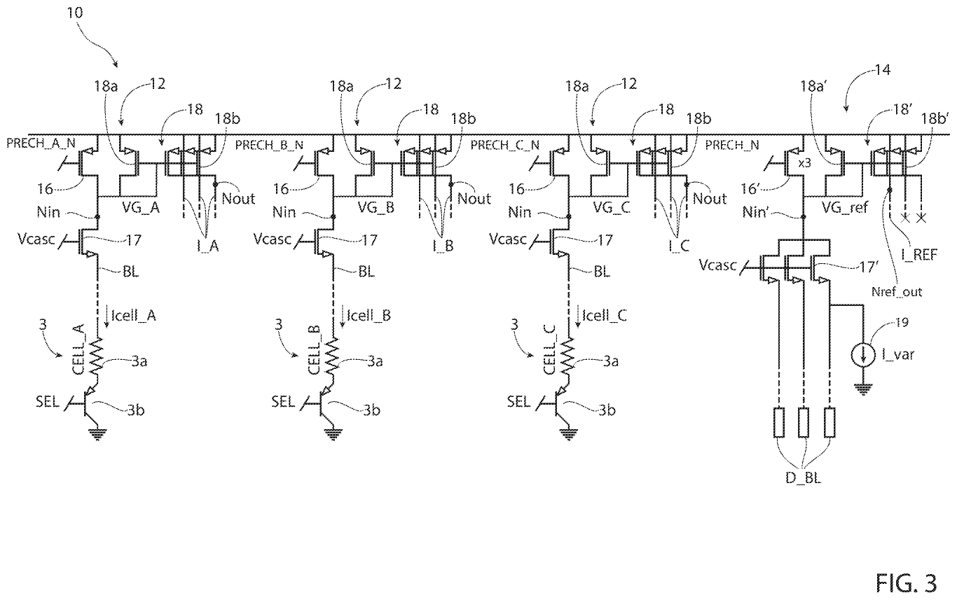

FIG. 3 shows in more detail a possible embodiment of a memory array-side portion of the sense amplifier 10, which comprises, coupled to the memory array 2, three reading branches 12, one coupled to each of the memory cells 3, Cell_A, Cell_B and Cell_C, storing the data to be read, in particular to the respective MBLs, and configured to receive respective cell currents I_{Cell_A}, I_{Cell_B}, I_{Cell_C} that flow in the same memory cells (Cell_A, Cell_B, Cell_C) depending on the resistance values of the respective storage elements 3a and therefore on the data stored. A selection signal SEL is shown coupled to the gate terminals of the access elements 3b of the memory cells 3, to denote the selection of the same cells for the reading operations.

According to an aspect of the present solution, the sense amplifier 10 further comprises an additional reference branch 14, which is coupled to the three dummy bit lines D_BL coupled to the memory cells 3′ of the not-addressed second sector S_1.

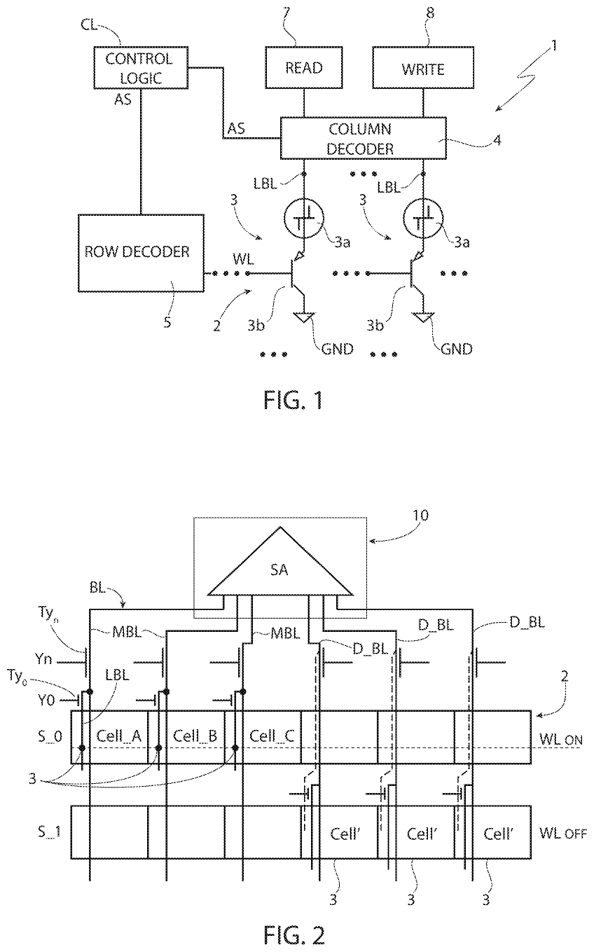

In detail, each of the reading branch 12 comprises a precharge transistor 16, which is a p-channel MOS transistor, having: source terminal connected to a supply node N_{dd}, which is set at a supply voltage V_{DD}, e.g., equal to 1.8V; gate terminal receiving a precharge signal PRECH_A_N, PRECH_B_N, PRECH_C_N, respectively for Cell_A, Cell_B and Cell_C (this precharge signal PRECH and the corresponding negation PRECH_N can be generated for example by the control logic CL, shown in FIG. 1, and can vary between 0 V and the supply voltage V_{DD}); and drain terminal connected to an input node Nᵢₙ.

The reading branch 12 further comprises a biasing transistor 17, in particular a NMOS transistor, connected between the aforesaid input node Nᵢₙ and a respective bit-line BL (as discussed above, to a respective main bit line MBL via a first-level decoding transistor TYn of the column decoder 4 and further to a local bit line LBL via a second-level decoding transistor Tyo). The biasing transistor 17 receives, on a gate terminal, a regulated voltage, so-called cascode voltage V_{case}, such as to impose a maximum allowed value for the bit line voltage V_{BL} on the respective bit-line (for example, 0.6V), thus preventing any possible stress and damage during reading of the datum stored. In addition, the biasing transistor 17 implements a capacitive decoupling between the respective bit-line and the input of the sense amplifier 10.

The reading branch 12 further comprises a current-mirror stage 18, which is configured to mirror the respective cell current (I_{Cell_A}, I_{Cell_B} or I_{Cell_C}) that flows through the biasing transistor 17 towards the input node Nᵢₙ and to provide three mirrored currents (I_A, I_B or I_C), i.e., three duplicated or copies of the same cell current.

In particular, the current-mirror stage 18 comprises a mirror transistor (PMOS) 18a coupled in parallel to the precharge transistor 16, between the supply node N_{dd} and the input node Nᵢₙ and diode-connected (i.e., having drain terminal shorted to the gate terminal); and three parallel-connected mirrored transistors (PMOS) 18b, coupled between the supply node N_{dd} and a respective current-mirroring output node Nₒᵤₜ, providing a respective mirrored current (i.e., a respective copy of the same cell current). The voltage of the common gate terminal of the mirror and mirrored transistors 18a, 18b is denoted with VG_{_A}, VG_{_B}, VG_{_C}, respectively for Cell_A, Cell_B and Cell_C.

In a corresponding manner, the reference branch 14 comprises a respective precharge transistor 16′, which is a p-channel MOS transistor, coupled between the supply node N_{dd} and a respective input node Nᵢₙ′ and having gate terminal receiving a precharge signal PRECH_N.

The reference branch 14 comprises three biasing transistors 17′, in particular NMOS transistors, connected between the aforesaid input node Nᵢₙ′ and a respective dummy bit-line D_BL and receiving, on the gate terminals, the cascode voltage V_{case}. In particular, the source terminal of one of the biasing transistors 17′ is further coupled to a current generator 19, which provides a variable current I_var.

The reference branch 14 further comprises a respective current-mirror stage 18′, configured to mirror the current at the aforesaid input node Nᵢₙ′ (being the sum of the variable current I_var and the remaining precharge currents from dummy bit lines D_BLs), in order to provide a reference current I_REF at a respective reference output N_{ref_out}.

The current-mirror stage 18′ has a configuration similar to that of the current-mirror stages 18 of the reading branches 12 (with mirror transistor 18a′ and three mirrored transistors 18b′), although one of the mirrored transistors 18b′ is used to mirror the reference current I_REF (the other two mirrored transistors 18b′ being “dummy” and used to match the dynamics with the current-mirror stages 18 of the reading branches 12). The voltage of the common gate terminal of the mirror and mirrored transistor 18a′, 18b′ is denoted with VG_{_Ref}.

After precharging, the cell currents Cell_A, Cell_B and Cell_C of the memory cells 3 are directly mirrored and copied (three times), to be sent to respective current comparators, as will now be discussed, with the bit line voltage V_{BL} granted by the regulated voltage V_{case}. During data reading, the precharge signals PRECH_A_N, PRECH_B_N, PRECH_C_N are set to a common value PRECH_N.

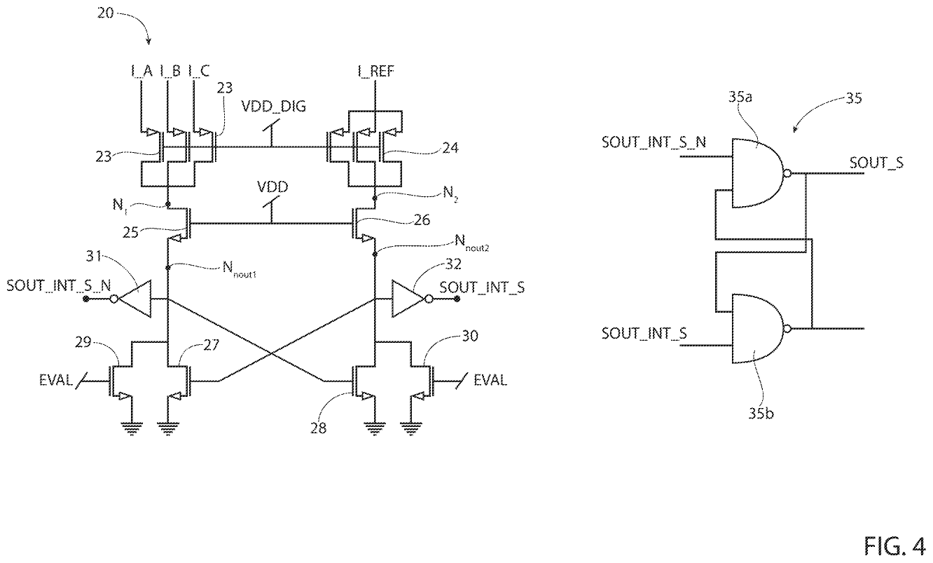

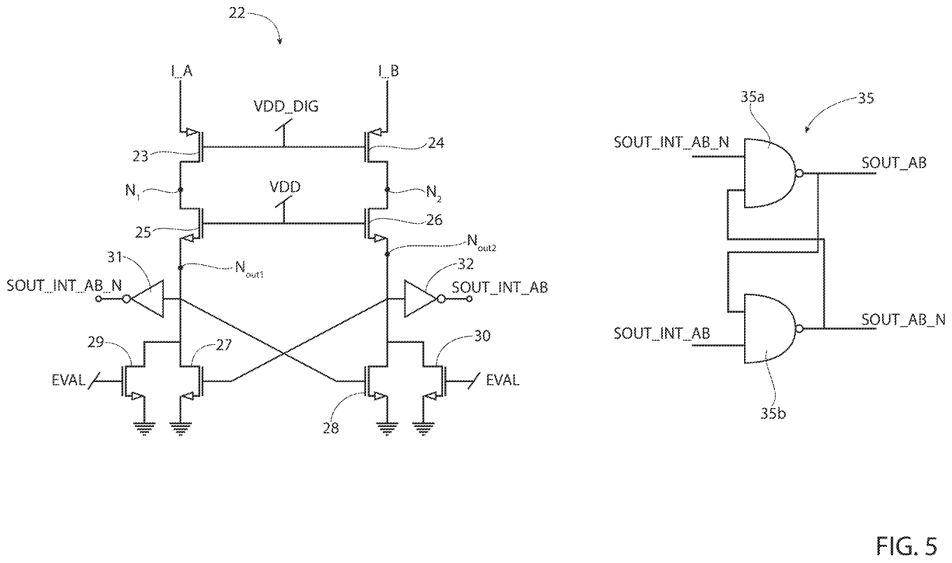

With reference to FIGS. 4 and 5, the comparator-side portion of the sense amplifier 10 is now discussed, which comprises: a subset definition comparator 20 coupled to the three reading branches 12 and to the reference branch 14, configured to compare the sum of the mirrored cell currents (I_{_A}, I_{_B}, I_{_C}) received from the current-mirror stages 18, in particular provided at the respective current-mirroring output nodes Nₒᵤₜ, with the reference current I_REF, so as to provide a subset comparison output signal SOUT_S; and three differential comparators 22 coupled to a respective pair of the three reading branches 12, configured to compare a respective pair of mirrored cell currents (I_{_A}, I_{_B}, I_{_C}) received from the current-mirror stages 18.

In a possible embodiment, the three differential comparators 20 are configured to perform the following current comparisons: Cell_A vs Cell_B, to provide a first comparison output signal SOUT_AB; Cell_A vs Cell_C, to provide a second comparison output signal SOUT_AC; and Cell_B vs Cell_C, to provide a third comparison output signal SOUT_BC. Based on the result of the above comparisons, the symbol stored by the read memory cells 3 (Cell_A, Cell_B, Cell_C) can be determined as shown in the following Table.

| SOUT_S | SOUT_AB | SOUT_AC | SOUT_BC | Cell_A | Cell_B | Cell_C | Symb. | Bit map |
|---|---|---|---|---|---|---|---|---|
| 1 | — | 1 | 1 | 1 | 1 | 0 | 0 | 11 |
| 1 | 1 | — | 0 | 1 | 0 | 1 | 1 | 10 |
| 1 | 0 | 0 | — | 0 | 1 | 1 | 2 | 01 |
| 0 | — | — | — | 0 | 0 | 0 | 3 | 11 |

In more detail, as shown in FIG. 4, the subset definition comparator 20 of the sense amplifier 10 has a fully symmetric structure and comprises an input stage with a first group of three input transistors 23, in particular PMOS transistors, coupled between a respective current-mirroring output node Nₒᵤₜ, to receive a respective one of the mirrored cell currents I_{_A}, I_{_B}, I_{_C} from the current-mirror stages 18, and a first internal node N₁, at which the sum of the mirrored cell currents I_{_A}, I_{_B}, I_{_C} is provided; and a second group of three input transistors 24, in particular PMOS transistors, coupled between the reference output N_{ref_out}, in order to receive the reference current I_REF, and a second internal node N₂, at which the same reference current I_REF is provided. The input transistors 23, 24 of the first and second groups have gate terminals coupled together to a same line set at a digital supply voltage V_{DD}_DIG, e.g., equal to 1V (lower than the above supply voltage V_{DD}).

The subset definition comparator 20 further comprises a limiting stage with a first limiting transistor 25, in particular NMOS transistor, coupled between the first internal node N₁ and a first output node Nₒᵤₜ₁ of the subset definition comparator 20; and a second limiting transistor 26, in particular NMOS transistor, coupled between the second internal node N₂ and a second output node Nₒᵤₜ₂ of the subset definition comparator 20. The first and second limiting transistors 25, 26 have gate terminals coupled together to a same line, set (during the reading operation) at the supply voltage V_{DD}. The limiting stage is configured to limit the outputs and, moreover, to turn off the subset definition comparator 20.

The subset definition comparator 20 further comprises a latching core with a first output transistor 27 and a second output transistor 28, which are of the NMOS type and are connected in a cross-coupled configuration. In particular, the first output transistor 27 has drain terminal connected to the first output node Nₒᵤₜ₁ and source terminal connected to a ground reference terminal; and the second output transistor 28 has drain terminal connected to the second output node Nₒᵤₜ₂ and source terminal connected to the ground reference terminal. The gate terminal of the first output transistor 27 is connected to the drain terminal of the second output transistor 28 and, likewise, the gate terminal of the second output transistor 28 is connected to the drain terminal of the first output transistor 27.

The subset definition comparator 20 further comprises a first evaluation transistor 29, coupled in parallel to the first output transistor 27 and having gate terminal receiving a control signal EVAL (which can also be generated by the above control logic CL and may vary between 0 V and the supply voltage V_{dd}); and a second evaluation transistor 30, coupled in parallel to the second output transistor 28 and having gate terminal receiving the same control signal EVAL.

The subset definition comparator 20 further comprises a first inverter 31, coupled to the first output node Nₒᵤₜ₁ and providing at a respective output a first (negated) output signal, denoted as SOUT_INT_S_N, in the digital domain; and a second inverter 32, coupled to the second output node Nₒᵤₜ₂ and providing at a respective output a second output signal, denoted as SOUT_INT_S, in the digital domain.

As shown in the same FIG. 4, the sense amplifier 10 comprises a latch circuit 35, coupled at the output of the subset definition comparator 20.

The latch circuit 35 comprises two NAND gates 35a, 35b, having a respective first input connected to the first and, respectively, the second output nodes Nₒᵤₜ₁, Nₒᵤₜ₂ of the subset definition comparator 20, so as to receive, respectively, the first output signal SOUT_INT_S_N and the second output signal SOUT_INT_S. The second input of each NAND gate 35a, 35b is connected to the output of the other NAND gate 35b, 35a. The output of NAND gate 35a moreover constitutes the output of the latch circuit 35, which provides the subset comparison output signal SOUT_S.

The subset definition comparator 20 therefore allows to compare the sum of the cell currents I_{Cell_A}, I_{Cell_B}, I_{Cell_C} with the reference current I_{REF}, in order to determine the subset, ‘0’ or ‘1’, to which the stored data belong.

In particular, the following conditions apply: SOUT_INT_S_N=‘0’ and SOUT_INT_S=‘1’ for subset ‘1’; SOUT_INT_S_N=‘1’ and SOUT_INT_S=‘0’ for subset ‘0’; SOUT_S=‘1’ for subset ‘1’; and SOUT_S=‘0’ for subset ‘0’.

As shown in FIG. 5, each of the differential comparators 22 (FIG. 5 shows, by way of example, the one operating the comparison between Cell_A and Cell_B, to provide the first comparison output signal SOUT_AB) has a fully symmetric structure that is quite similar to the one of the subset definition comparator 20 (so that it will not be disclosed in detail again and the same reference numerals will be used to denote similar elements).

In particular, in the case of the differential comparator 22, the input stage comprises just a first input transistor 23, of the PMOS type, coupled between a respective current-mirroring output node Nₒᵤₜ, in this case to receive the mirrored cell current I_{_A} from the mirror stage 18 of a first one of the reading branches 12 and the first internal node N₁, at which the same mirrored cell current I_{_A} is provided; and just a second input transistor 24, of the PMOS type, coupled between a respective current-mirroring output node Nₒᵤₜ of a second one of the reading branches 12, in this case to receive the mirrored cell current I_{_B}, and the second internal node N₂, at which the same mirrored cell current I_{_B} is provided.

Each of the differential comparators 22 further comprises a respective latch circuit 35, altogether similar to the one discussed with reference to FIG. 4, coupled to the subset definition comparator 20.

The latch circuit 35 in this case receives first and second output signals SOUT_INT_AB_N and SOUT_INT_AB from the first and, respectively, the second output nodes Nₒᵤₜ₁, Nₒᵤₜ₂ of the differential comparator 22 and provides a latched comparison output signal SOUT_AB (and negated version SOUT_AB_N).

In particular, the comparison output signal SOUT_AB has a first logic value, ‘1’, in case I_{Cell_A}>I_{Cell_B}, and a second logic value, ‘0’, in case I_{Cell_B}>I_{Cell_A}.

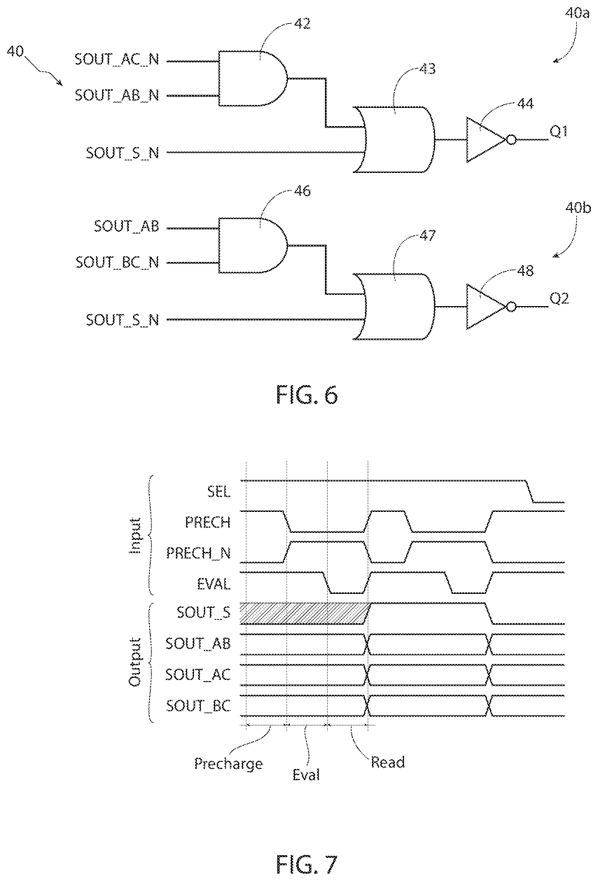

As shown in FIG. 6, the sense amplifier further comprises a digital decoding logic 40, which is coupled to the latch circuits 35 at the output of the subset definition comparator 20 and of the three differential comparators 22.

This digital decoding logic 40 is designed to provide the first and second bits (denoted here with Q1 and Q2) of the symbols (bit maps) associated with the stored data, according to the following table (which again follows the already discussed data decoding scheme).

| SOUT_AB | SOUT_AC | SOUT_BC | SOUT_S | Q1 | Q2 |
|---|---|---|---|---|---|
| — | 1 | 1 | 1 | 1 | 1 |
| 1 | — | 0 | 1 | 1 | 0 |
| 0 | 0 | — | 1 | 0 | 1 |
| — | — | — | 0 | 0 | 0 |

In particular, the digital decoding logic 40 is configured to implement the following logic expressions:

Q1=(̅S̅O̅U̅T̅_̅S̅+̅S̅O̅U̅T̅_̅A̅B̅*̅S̅O̅U̅T̅_̅A̅C̅)̅

Q2=(̅S̅O̅U̅T̅_̅S̅+̅S̅O̅U̅T̅_̅A̅B̅*̅S̅O̅U̅T̅_̅B̅C̅)̅

where ‘+’ denotes the ‘OR’ logical operator and ‘*’ the ‘AND’ logical operator.

In more detail, the digital decoding logic 40 comprises a first stage 40a designed to provide the first bit Q1 and a second stage 40b designed to provide the second bit Q2.

The first stage 40a comprises: an AND gate 42, which receives at its input the negated version of the latched comparison output signals SOUT_AC and SOUT_AB; an OR gate 43, which has a first input coupled to the output of the AND gate 42 and a second input receiving the negated version of the subset comparison output signal SOUT_S; and a logic inverter 44, coupled at the output of the OR gate 43 and providing at a respective output the first bit Q1.

The second stage 40b comprises: an AND gate 46, which receives at its input the latched comparison output signal SOUT_AB and the negated version of the latched comparison output signal SOUT_BC; an OR gate 47, which has a first input coupled to the output of the AND gate 46 and a second input receiving the negated version of the subset comparison output signal SOUT_S; and a logic inverter 48, coupled at the output of the OR gate 47 and providing at a respective output the second bit Q2.

FIG. 7 shows some of the above discussed signals related to the reading process performed by the sense amplifier 10.

In brief, this reading process comprises the following phases:
a precharge phase, related to the selection of column and word lines; at the end of the precharge phase, a suitable current in the sense amplifier branches is generated, and an added contribution of main bit line precharge is minimized by the conclusion of a transient selection time;
an evaluation phase, which allows for stabilizing the gate terminals of the mirror and mirrored transistors 18a, 18b in the current-mirror stages 18, which were previously at the supply voltage VDD, ensuring that the currents are accurately mirrored (the same current-mirror stages 18 reach their steady state); and
a reading and latching phase, which starts with the “opening” of the evaluation transistors 29, 30 in the comparators; during this phase, each latching core compares the respective currents and outputs the corresponding result that is then stored by the latches at the output of the same comparators (with the digital logic that determines the two data bits Q1, Q2 for each symbol).

According to an aspect of the present solution, the sense amplifier can be further provided with an error detection logic, which is configured to detect the occurrence of particular combinations of the four output signals (the subset comparison output signal SOUT_S and the three comparison output signals SOUT_AB, SOUT_AC and SOUT_BC), that are indicative of reading errors, in particular the following two combinations: 1010 and 1101.

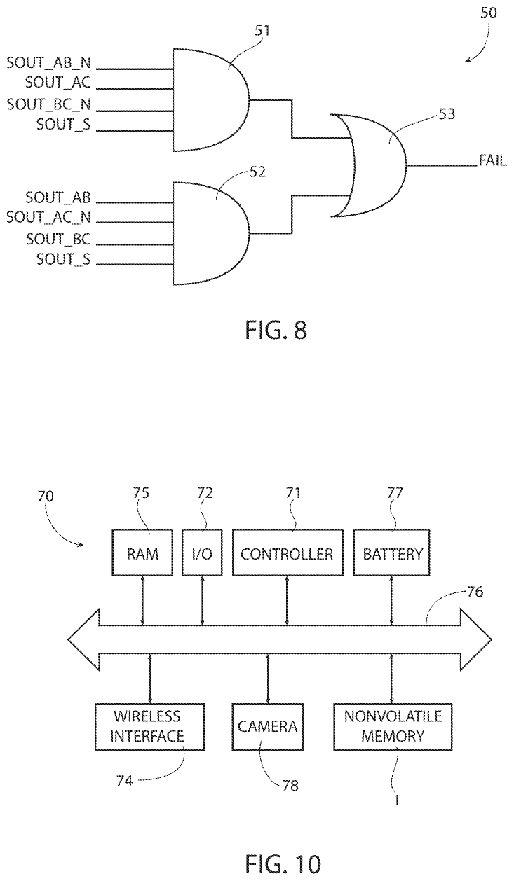

FIG. 8 shows a possible implementation of this error detection logic, denoted with 50, which comprises: a first AND gate 51, receiving at its four inputs the negated version of the comparison output signals SOUT_AB, the comparison output signal SOUT_AC, the negated version of the comparison output signal SOUT_BC and the subset comparison output signal SOUT_S; a second AND gate 52, receiving at its four inputs the comparison output signals SOUT_AB, the negated version of the comparison output signal SOUT_AC, the comparison output signal SOUT_BC and the subset comparison output signal SOUT_S; and an OR gate 53, receiving at its inputs the outputs of the first and second AND gates 50, 51 and providing at its output a ‘FAIL’ signal, indicative of the occurrence of a failure in the reading of the data stored.

In this error detection logic 50, the first AND gate 51 provides a ‘1’ logic output in case of the occurrence of the first combination (1010) of the four output signals; the second AND gate 52 provides a ‘1’ logic output in case of the occurrence of the second combination (1101); the OR gate 53 provides the ‘FAIL’ signal with a ‘1’ logic output in case the first or the second combination of the four outputs occurs.

Moreover, the above discussed architecture of the sense amplifier 10 advantageously allows to implement a verify function, for verifying set and reset writing operations ON the memory cells 3.

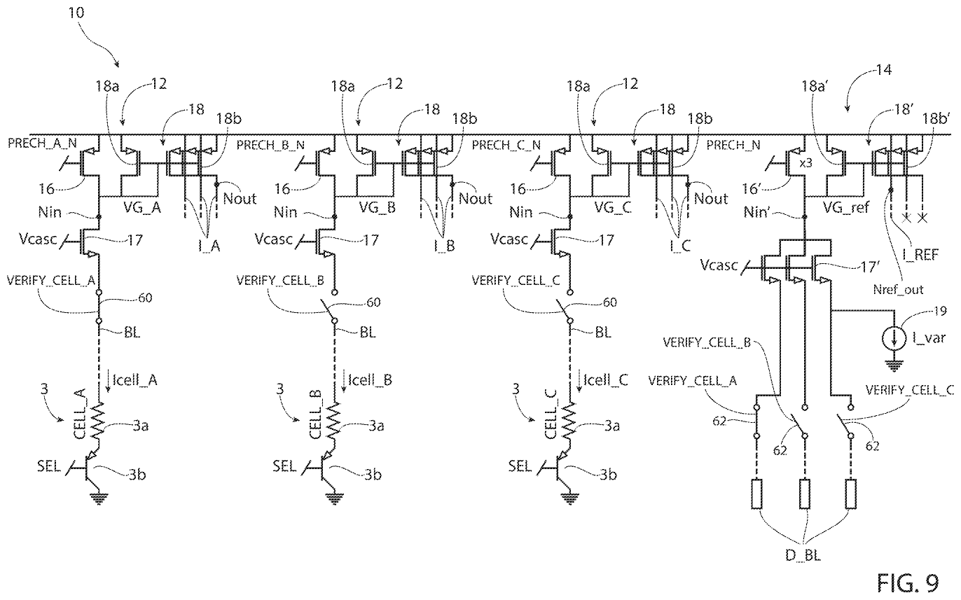

As shown in FIG. 9, which substantially corresponds to FIG. 3 discussed above, a respective verify switch 60 can be introduced in each of the reading branches 12 of the sense amplifier 10, in particular between the biasing transistor 17 and the bit line BL coupled to the respective memory cell 3. Each verify switch 60 is controlled by a respective verify control signal VERIFY_CELL_A, VERIFY_CELL_B, VERIFY_CELL_C (which may be generated by the control logic CL of the non-volatile storage device 1, shown in FIG. 1).

In a corresponding manner, further verify switches 62 are introduced in each of the reference branches 14 of the sense amplifier 10, in particular between the respective biasing transistor 17′ and the respective dummy bit-line D_BL. The further verify switches 62 are controlled by the same verify control signal VERIFY_CELL_A, VERIFY_CELL_B, VERIFY_CELL_C.

The verify switches 60, 62 can be operated to disconnect the memory cells 3 that are not to be verified, leaving the memory cell 3 to be verified connected to the sense amplifier 10. As an example, in case Cell_A is to be verified, the VERIFY_CELL_B and VERIFY_CELL_C signals disconnect the respective cells Cell_B and Cell_C and their respective dummy bit lines. The precharge signals behave similarly, with the precharge signals of Cell_B and Cell_C (PRECH_B_N and PRECH_C_N) that remain down for the entire verify process, keeping the common gate terminals of the mirror and mirrored transistors (VG_{_B} and VG_{_C}) fixed at the supply voltage VDD.

The comparator used for the verify operation is the subset definition comparator 20, which receives the cell current I_{Cell_A} (as discussed, cell currents I_{Cell_B}, I_{Cell_C} are in this case not mirrored) and compares it with the reference current I_REF, so as to provide a subset comparison output signal SOUT_S, in this case indicative of the result of the verify operation.

The other comparators, i.e., the three differential comparators 22, are not needed for the verify operation, so that they can be turned off by the first and second limiting transistors 25, 26, with their gate terminals coupled in this case to a same disabling or turn-off signal V_DIS (for example set to ground).

The advantages that the present solution allows to achieve are clear from the foregoing description.

In particular, it is underlined that the disclosed sense amplifier 10 offers an improved reading robustness and reliability, due in particular to the capacitance matching features implemented via the additional reference branch 14, during reading operations.

Moreover, the same sense amplifier 10 provides a verify capability and also the possibility of an early detection of reading errors (via the error detection logic 50).

The sense amplifier 10 has a reduced power consumption with respect to known solutions, thanks to the direct comparison of the cell currents (which are mirrored at the PMOS side of the sense amplifier branches, in parallel to the biasing transistor 17), and an improved area occupation, thanks to the use of fewer and smaller transistors.

The resulting non-volatile storage device 1 can therefore find use in numerous contexts. For instance, FIG. 10 illustrates a portion of an electronic apparatus 70, which may, for example, be: a PDA (Personal Digital Assistant); a portable or desktop computer, possibly with capacity of wireless data transfer; a mobile phone; a digital audio player; a camera or a camcorder; or further devices capable of processing, storing, transmitting, and receiving information.

The electronic apparatus 70 may comprise: a controller 71 (for example, provided with a microprocessor, a DSP or a microcontroller); an input/output device 72 (for example, provided with a keypad and a display), for input and display of data; the above discussed non-volatile storage device 1; a wireless interface 74, for example an antenna, for transmitting and receiving data through a radiofrequency wireless communication network; and a RAM 75. All the components of the electronic apparatus 70 are coupled through a bus 76. A battery 77 can be used as electrical power supply source in the electronic apparatus 70, which may moreover be equipped with a camera, or video camera or camcorder 68. Moreover, the controller 71 can control the non-volatile storage device 1, for example co-operating with the control logic CL.

In addition, it is clear that modifications and variations may be made to what has been described and illustrated herein, without, thereby, departing from the scope of the present disclosure.

For instance, it is underlined that the sense amplifier 10 can be used for memory cells 3, which may be different from memory cells of a PCM type, e.g., for ST-RAM or RRAM memory cells.

Moreover, different coding schemes can be implemented; in general, according to possible coding schemes, given a set of codewords or symbols obtainable by the stored values of a determined number of non-volatile memory cells 3 in a group, information can be stored in at least two subsets of this set of symbols comprising each at least a symbol, each symbol in a same subset having a same Hamming weight and each symbol belonging to one subset having a Hamming distance equal or greater than two with respect to each symbol belonging to another subset.

For instance, the number of memory cells 3 in a group could be four (instead of three) as shown in the Table below. With four cells (Cell_A, Cell_B, Cell_C, Cell_D) and two subsets (SB1, SB2), eight symbols could be defined and eight symbols for coding of the stored data.

| Cell_A | Cell_B | Cell_C | Cell_D | Subset | Symbol | Bitmap |
|---|---|---|---|---|---|---|
| 1 | 0 | 0 | 0 | SB1 | 0 | 000 |
| 0 | 1 | 0 | 0 | SB1 | 1 | 001 |
| 0 | 0 | 1 | 0 | SB1 | 2 | 010 |
| 0 | 0 | 0 | 1 | SB1 | 3 | 011 |
| 0 | 1 | 1 | 1 | SB2 | 4 | 100 |
| 1 | 0 | 1 | 1 | SB2 | 5 | 101 |
| 1 | 1 | 0 | 1 | SB2 | 6 | 110 |
| 1 | 1 | 1 | 0 | SB2 | 7 | 111 |

Also in this case, when reading (or decoding) the data stored in the coded manner, it is first determined the subset the data belongs to. The sense amplifier 10 therefore also in this case first performs a determination of the subset to which a symbol to be read belongs to (comparing a signal indicative of the sum of the cell currents of all the memory cells 3 in the group with a reference current, via the subset definition comparator 20) and then performs a determination of the coded symbol based on a suitable number of pairwise comparisons between the various cell currents (via the differential comparators 22).

A sense amplifier (10), for a non-volatile memory device (1) is summarized as including an array (2) of a plurality of memory cells (3) organized in wordlines (WL) and bitlines (BL), wherein groups of memory cells store respective symbols formed by stored logic states, logic high (‘1’) or logic low (‘0’), of the memory cells of the group; said sense amplifier (10) comprising: a number of reading branches (12), each one coupled, during a reading process, to a respective bitline (BL) of an addressed memory cells (3) of a respective group and configured to provide output currents (I_A, I_B, I_C) based on a respective cell current (I_{Cell_A}, I_{Cell_B}, I_{Cell_C}) flowing through the addressed memory cell (3); a number of first comparators (22), coupled to a respective pair of the reading branches (12) and configured to compare a respective pair of the output currents to provide first comparison output signals; a second comparator (20), coupled to the reading branches (12) and configured to compare a sum of the respective output currents (I_A, I_B, I_C) with a reference current (I_REF) to provide a second comparison output signal; and a decoding logic (40), configured to determine, based on the first and second comparison output signals, a read symbol corresponding to the group of memory cells, wherein the sense amplifier (10) further comprises a reference branch (14), which is configured to provide the reference current (I_REF) and is coupled to a number of dummy bitlines (D_BL) associated with memory cells (3) not selected for the reading process, the dummy bitlines (D_BL) corresponding in number to the bitlines (BL) of the addressed memory cells (3) of the respective group.

The reference branch (14) is configured to provide a capacitive matching during the reading process, matching a capacitive load of the reading branches (12) associated with the addressed memory cells (3).

The array is divided into sectors and the memory cells (3) not selected for the reading process, with which the dummy bitlines (D_BL) are associated, belong to a sector (S_1) of the array (2) different from a respective sector (S_0) to which the addressed memory cells (3) belong.

Each reading branch (12) comprises: a precharge transistor (16), of a p-channel MOS type, having source terminal connected to a supply node (N_{dd}), gate terminal receiving a precharge signal (PRECH_A) and drain terminal connected to an input node (Nᵢₙ); a biasing transistor (17), of a n-channel MOS type, connected between the input node (Nᵢₙ) and a respective bit-line (BL) and configured to receive, on a gate terminal, a regulated voltage (V_{case}); and a current-mirror stage (18), which is configured to mirror the respective cell current (I_{Cell_A}) and provide a number of output currents (I_A) as mirrored copies of the respective cell current (I_{Cell_A}), to be provided to the first and second comparators (22, 20).

The current-mirror stage (18) comprises a diode-connected mirror transistor (18a), of the PMOS type, coupled in parallel to the precharge transistor (16), between the supply node (N_{dd}) and the input node (Nᵢₙ); and a number of parallel-connected mirrored transistors (18b), coupled between the supply node (N_{dd}) and a respective current-mirroring output node (Nₒᵤₜ), providing a respective one of the number of output currents (I_A).

The reference branch (14) comprises a respective precharge transistor (16′), of a p-channel MOS transistor, coupled between the supply node (N_{dd}) and a respective input node (Nᵢₙ′) and having gate terminal receiving a precharge signal (PRECH); a number of biasing transistors (17′), of the NMOS type, connected between the input node (Nᵢₙ′) and a respective dummy bit-line (D_BL) and configured to receive, on gate terminals, the regulated voltage (V_{case}), the source terminal of one of the biasing transistors (17′) being further coupled to a current generator (19) which provides a variable current (I_var); and a respective current-mirror stage (18′), configured to mirror the current at the aforesaid input node (Nᵢₙ′), in order to provide the reference current (I_REF) at a respective reference output (N_{ref_out}), to be provided to the second comparator (20).

The current-mirror stage (18′) comprises a diode-connected mirror transistor (18a′), of the PMOS type, coupled in parallel to the precharge transistor (16′), between the supply node (N_{dd}) and the input node (Nᵢₙ); and a number of parallel-connected mirrored transistors (18b′), coupled between the supply node (N_{dd}) and a respective current-mirroring output node (N_{ref_out}), wherein only one of the mirrored transistors (18b′) is used to provide the reference current (I_REF) at the respective reference output (N_{ref_out}), the other mirrored transistors being “dummy” and used to match the dynamics with the current-mirror stages (18) of the reading branches (12).

The second comparator (20) comprises: an input stage with a first group of input transistors (23), coupled between a respective one of the current-mirror stages (18) and a first internal node (N₁), at which the sum of the respective output currents (I_A, I_B, I_C) is provided and a second group of input transistors (24), coupled between the reference branch (14) to receive the reference current (I_REF) and a second internal node (N₂); a limiting stage with a first limiting transistor (25), coupled between the first internal node (N₁) and a first output node (Nₒᵤₜ₁) of the second comparator (20) and a second limiting transistor (26), coupled between the second internal node (N₂) and a second output node (Nₒᵤₜ₂) of the second comparator (20), the first and second limiting transistors (25, 26) having gate terminals coupled together to a common biasing line; and a latching core with a first output transistor (27) and a second output transistor (28), connected in a cross-coupled configuration between the first output node (Nₒᵤₜ₁), respectively the second output node (Nₒᵤₜ₂), and a reference terminal.

Each first comparator (22) has an input stage comprising a first input transistor (23), coupled between a respective reading branch (12) to receive a first output current (I_A) of the pair of output currents (I_A, I_B) to be compared and a first internal node (N₁) and a second input transistor (24), coupled between a respective reading branch (12) to receive a second output current (I_B) of the pair of output currents (I_A, I_B) to be compared and a second internal node (N₂); a limiting stage with a first limiting transistor (25), coupled between the first internal node (N₁) and a first output node (Nₒᵤₜ₁) of the first comparator (22) and a second limiting transistor (26), coupled between the second internal node (N₂) and a second output node (Nₒᵤₜ₂) of the first comparator (22), the first and second limiting transistors (25, 26) having gate terminals coupled together to a common biasing line; and a respective latching core with a first output transistor (27) and a second output transistor (28), connected in a cross-coupled configuration between the first output node (Nₒᵤₜ₁), respectively the second output node (Nₒᵤₜ₂), and a reference terminal.

Each of the reading branches (12) comprises a respective verify switch (60), coupled between the biasing transistor (17) and the respective bit line (BL), designed to be controlled by a respective verify control signal (VERIFY_CELL_A, VERIFY_CELL_B, VERIFY_CELL_C) during a verify operation, in order to disconnect the memory cells (3) that are not to be verified, leaving only a memory cell (3) to be verified connected to the sense amplifier (10); and wherein each of the reference branches (14) comprises a further verify switch (62) between the respective biasing transistor (17′) and the respective dummy bit-line (D_BL), the further verify switches (62) designed to be controlled by the verify control signals to disconnect the respective dummy bit-line (D_BL) from the sense amplifier (10).

During the verify operation, the current-mirror stages (18) of the reading branches (12) associated with the memory cells (3) that are not to be verified are disabled; and wherein the second comparator (20) is configured to implement the verify process, comparing the cell current of the memory cell (3) to be verified with the reference current (I_REF), and providing a comparison output signal (SOUT_S), in this case indicative of the result of the verify operation, with the first comparators (22) being disabled.

The sense amplifier, further comprising an error detection logic (50), which is configured to detect the occurrence of particular combinations of the first and second comparison output signals, being indicative of reading errors.

Given a set of symbols obtainable by the stored values in the memory cells (3) in a group, information are stored in at least two subsets (SB1, SB2) of said set of symbols, comprising each at least one symbol, each symbol in a same subset having a same Hamming weight and each symbol belonging to one subset (SB1) having a Hamming distance equal or greater than two with respect to each symbol belonging to another subset (SB2); wherein the first comparator (20) is configured to allow determination of the subset to which a symbol to be read belongs to and the second comparators (22) are configured to perform pairwise comparisons between the output currents (I_A, I_B) from the reading branches (12) to allow determination of the particular symbol in the subset.

Groups of three memory cells store respective symbols of two bits; and wherein the sense amplifier (10) comprises three reading branches (12) and three of the first comparators (22).

A memory device (1) is summarized as including an array (2) of memory cells (3), the memory cells (3) being of the type in which the stored logic state is changed through application of a current and the stored logic state in the memory cell is read by reading a current flowing therethrough; further comprising a plurality of sense amplifiers (10).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A sense amplifier for a non-volatile memory device including an array of a plurality of memory cells organized in wordlines and bitlines, groups of memory cells store respective symbols formed by stored logic states of the memory cells of the group, the sense amplifier comprising:
a number of reading branches, each one coupled, during a reading process, to a respective bitline of an addressed memory cell of a respective group, and configured to provide output currents based on a respective cell current flowing through the addressed memory cell;
a number of first comparators coupled to a respective pair of the reading branches, and configured to compare a respective pair of the output currents to provide first comparison output signals;
a second comparator coupled to the reading branches, and configured to compare a sum of respective output currents with a reference current to provide a second comparison output signal;
a decoding logic configured to determine, based on the first and second comparison output signals, a read symbol of a corresponding to group of memory cells; and
a reference branch, which is configured to provide the reference current and is coupled to a number of dummy bitlines associated with memory cells not selected for the reading process, the dummy bitlines corresponding in number to the bitlines of the addressed memory cells of the respective group.

2. The sense amplifier according to claim 1, wherein the reference branch is configured to provide a capacitive matching during the reading process, matching a capacitive load of the reading branches associated with the addressed memory cells.

3. The sense amplifier according to claim 1, wherein the array is divided into sectors, and the memory cells not selected for the reading process, with which the dummy bitlines are associated, belong to a sector of the array different from a respective sector to which the addressed memory cells belong.

4. The sense amplifier according to claim 1, wherein each of the reading branches includes:
a precharge transistor, of a p-channel MOS (PMOS) type, having a source terminal connected to a supply node, a gate terminal configured to receive a precharge signal, and a drain terminal connected to an input node;
a biasing transistor, of a n-channel MOS (NMOS) type, connected between the input node and a respective bitline and configured to receive, on a gate terminal, a regulated voltage; and
a current-mirror stage, which is configured to mirror the respective cell current and provide a number of output currents as mirrored copies of the respective cell current, to be provided to the first and second comparators.

5. The sense amplifier according to claim 4, wherein the current-mirror stage includes:
a diode-connected mirror transistor, of the PMOS type, coupled in parallel to the precharge transistor, between the supply node and the input node; and
a number of parallel-connected mirrored transistors, coupled between the supply node and a respective current-mirroring output node, providing a respective one of the number of output currents.

6. The sense amplifier according to claim 4, wherein the reference branch includes:
a respective precharge transistor, of a p-channel MOS transistor, coupled between the supply node and a respective input node, and having gate terminal configured to receive a respective precharge signal;
a number of biasing transistors, of the NMOS type, connected between the respective input node and a respective dummy bit-line, and configured to receive, on gate terminals, the regulated voltage, the source terminal of one of the number of biasing transistors being coupled to a current generator configured to provide a variable current; and
a respective current-mirror stage configured to mirror the current at the respective input node, in order to provide the reference current at a respective reference output, to be provided to the second comparator.

7. The sense amplifier according to claim 6, wherein the respective current-mirror stage includes:
a diode-connected mirror transistor, of the PMOS type, coupled in parallel to the respective precharge transistor, between the supply node and the respective input node; and
a number of parallel-connected mirrored transistors, coupled between the supply node and a respective current-mirroring output node, one of the number of parallel-connected mirrored transistors being used to provide the reference current at the respective reference output, the other mirrored transistors of the number of parallel-connected mirrored transistors being dummy transistors used to match dynamics with the current-mirror stages of the reading branches.

8. The sense amplifier according to claim 4, wherein the second comparator includes:
an input stage including a first group of input transistors coupled between a respective one of the current-mirror stages and a first internal node, at which a sum of the respective output currents is provided, and a second group of input transistors coupled between the reference branch to receive the reference current and a second internal node;
a limiting stage including a first limiting transistor coupled between the first internal node and a first output node of the second comparator, and a second limiting transistor coupled between the second internal node and a second output node of the second comparator, the first and second limiting transistors having gate terminals coupled together to a common biasing line; and
a latching core including a first output transistor and a second output transistor connected in a cross-coupled configuration between the first output node, respectively the second output node, and a reference terminal.

9. The sense amplifier according to claim 4, wherein each of the number of first comparators includes:
an input stage including:
a first input transistor coupled between a respective reading branch to receive a first output current of the respective pair of the output currents to be compared and a first internal node; and
a second input transistor coupled between a respective reading branch to receive a second output current of the respective pair of the output currents to be compared and a second internal node;
a limiting stage including:
a first limiting transistor coupled between the first internal node and a first output node of the first comparator; and
a second limiting transistor coupled between the second internal node and a second output node of the first comparator, the first and second limiting transistors having gate terminals coupled together to a common biasing line; and
a respective latching core including a first output transistor and a second output transistor connected in a cross-coupled configuration between the first output node, respectively the second output node, and a reference terminal.

10. The sense amplifier according to claim 4, wherein each of the reading branches includes a respective verify switch coupled between the biasing transistor and the respective bitline, configured to be controlled by a respective verify control signal during a verify operation, in order to disconnect the memory cells that are not to be verified, leaving a memory cell to be verified connected to the sense amplifier.

11. The sense amplifier according to claim 6, wherein each of the reference branches includes a further verify switch between a respective biasing transistor of the number of biasing transistors and the respective dummy bit-line of the reference branch, the further verify switch configured to be controlled by the verify control signals to disconnect the respective dummy bit-line from the sense amplifier.

12. The sense amplifier according to claim 10, wherein, during the verify operation, the current-mirror stages of the reading branches associated with the memory cells that are not to be verified are disabled; and
wherein the second comparator is configured to implement the verify operation by comparing the cell current of the memory cell to be verified with the reference current, and providing a comparison output signal, which is indicative of a result of the verify operation, with the first comparators being disabled.

13. The sense amplifier according to claim 1, further comprising:
an error detection logic, which is configured to detect an occurrence of particular combinations of the first and second comparison output signals, being indicative of reading errors.

14. The sense amplifier according to claim 1, wherein, given a set of symbols obtainable by the stored logic states in the memory cells in a group, information are stored in at least two subsets of the set of symbols, including each at least one symbol, each symbol in a same subset having a same Hamming weight and each symbol belonging to one subset having a Hamming distance equal or greater than two with respect to each symbol belonging to another subset;
wherein the second comparator is configured to allow determination of the subset to which a symbol to be read belongs to, and the number of first comparators are configured to perform pairwise comparisons between the output currents from the reading branches to allow determination of a particular symbol in the subset.

15. The sense amplifier according to claim 1, wherein groups of three memory cells store respective symbols of two bits; and
wherein the sense amplifier includes three reading branches and three of the first comparators.

16. A memory device comprising:
an array of memory cells in which a stored logic state in a memory cell is changed through application of a current and the stored logic state is read by reading a current flowing therethrough; and
a plurality of sense amplifiers, each of the plurality of sense amplifiers including:
a number of reading branches, each one coupled, during a reading process, to a respective bitline of an addressed memory cell of a respective group, and configured to provide output currents based on a respective cell current flowing through the addressed memory cell;
a number of first comparators coupled to a respective pair of the reading branches, and configured to compare a respective pair of the output currents to provide first comparison output signals;
a second comparator coupled to the reading branches, and configured to compare a sum of respective output currents with a reference current to provide a second comparison output signal;
a decoding logic configured to determine, based on the first and second comparison output signals, a read symbol of a corresponding to group of memory cells; and
a reference branch, which is configured to provide the reference current and is coupled to a number of dummy bitlines associated with memory cells not selected for the reading process, the dummy bitlines corresponding in number to the bitlines of the addressed memory cells of the respective group.

17. The memory device according to claim 16, wherein each reading branch includes:
a precharge transistor, of a p-channel MOS type, having a source terminal connected to a supply node, a gate terminal configured to receive a precharge signal, and a drain terminal connected to an input node;
a biasing transistor, of a n-channel MOS type, connected between the input node and a respective bitline and configured to receive, on a gate terminal, a regulated voltage; and
a current-mirror stage, which is configured to mirror the respective cell current and provide a number of output currents as mirrored copies of the respective cell current, to be provided to the first and second comparators.

18. The memory device according to claim 17, wherein the reference branch includes:
a respective precharge transistor, of a p-channel MOS transistor, coupled between the supply node and a respective input node, and having gate terminal configured to receive a respective precharge signal;
a number of biasing transistors, of the NMOS type, connected between the respective input node and a respective dummy bit-line, and configured to receive, on gate terminals, the regulated voltage, the source terminal of one of the number of biasing transistors being coupled to a current generator configured to provide a variable current; and
a respective current-mirror stage configured to mirror the current at the respective input node, in order to provide the reference current at a respective reference output, to be provided to the second comparator.

19. A sense amplifier comprising:
a plurality of reading branches, each of the plurality of reading branches configured to be coupled to a bitline of an addressed memory cell of a group of memory cells, and provide an output current based on a cell current flowing through the addressed memory cell;
a plurality of first comparators, each of the plurality of first comparators coupled to a pair of reading branches of the plurality of reading branches, and configured to provide a first comparison output signal based on a comparison of output currents of the pair of reading branches;
a second comparator coupled to the plurality of reading branches, and configured to provide a second comparison output signal based on a comparison of a sum of output currents of the plurality of reading branches with a reference current;
a decoding circuitry configured to determine, based on the first and second comparison output signals, a read symbol of the group of memory cells; and
a reference branch coupled to a number of dummy bitlines, and configured to provide the reference current, a number of the dummy bitlines corresponding to a number of bitlines of addressed memory cells of the group of memory cells.

20. The sense amplifier according to claim 19, wherein the reference branch is configured to provide a capacitive matching of a capacitive load of the plurality of reading branches.
